(19) United States
(12) Patent Application Publication
(10) Pub. No.: US 2021/0023673 A1
(43) Pub. Date: Jan. 28, 2021

(54) POLISHING HEAD AND WAFER POLISHING METHOD

(71) Applicant: SHIN-ETSU HANDOTAI CO., LTD., Tokyo (JP)

(72) Inventors: Junichi UENO, Shirakawa-shi (JP); Kaoru ISHII, Shirakawa-shi (JP)

(73) Assignee: SHIN-ETSU HANDOTAI CO., LTD., Tokyo (JP)

(21) Appl. No.: 17/041,619

(22) PCT Filed: Feb. 27, 2019
(86) PCT No.: PCT/JP2019/007421

§ 371 Date: Sep. 25, 2020

(30) Foreign Application Priority Data
Apr. 5, 2018 (JP) 2018-072874

(51) Int. Cl. B24B 37/30; H01L 21/304

(52) U.S. Cl. CPC B24B 37/30; H01L 21/304

(57) ABSTRACT

A polishing head includes at least: an annular ceramic ring; a template attached to the ceramic ring and having a backing pad integrated with a guide ring; and a back plate joined to the ceramic ring to form a space together with the backing pad and the ceramic ring. The polishing head holds a back surface of a wafer on a lower surface portion of the backing pad and brings a front surface of the wafer into sliding contact with a polishing pad attached on a turntable for polishing the wafer. An incompressible fluid is enclosed in the space, and has a viscosity of 10 mPa·s or more and 1200 mPa·s or less. A polishing head and polishing method is capable of reducing backing pad deformation at a small gap between the template and wafer, and improving polishing uniformity at the wafer outermost peripheral portion.

### TECHNICAL FIELD

The present invention relates to a polishing head and a wafer polishing method.

### BACKGROUND ART

As a method of polishing a semiconductor wafer, a polishing pad is attached on a turntable of a polishing apparatus, a polishing agent is supplied onto the polishing pad, and a polishing head holding a wafer is slid on the polishing pad to polish the wafer.

FIG. 3 is a view showing an example of a conventional polishing head structure. In a the polishing head 1′, a template 5 having a backing pad 3 integrated with a guide ring 4 made of a resin such as a glass epoxy material is attached to an annular ceramic ring 2. A space 7 is formed between a back plate 6 and the ceramic ring 2 to which the template 5 is attached. Water 8′ as an incompressible fluid is enclosed in the space 7 (see Patent Documents 1, 2, 3).

In the polishing head 1′, the pressure applied from the back plate via the incompressible fluid enclosed in the space 7 pushes the backing pad 3 of the template 5, and the load is transmitted to polish a wafer W pasted with water on the template.

By charging the space 7 in the polishing head 1′ with the water 8′, the deformation of the backing pad 3 is reduced at a small gap formed between the template 5 and the wafer W. Nevertheless, the polishing uniformity around the outermost peripheral portion of the wafer W is not sufficient.

In the conventional polishing head, water is enclosed as one of incompressible fluids in the space (fluid enclosing portion). Since the viscosity of water is 0.890 mPa·s (25° C.), the deformation of the backing pad 3 at the small gap formed between the template 5 and the wafer W causes the wafer W to be strongly pressed against a polishing pad 22 on a turntable 23, thereby promoting the polishing.

FIG. 4 is an enlarged view of an exemplary section surrounded by the dashed line in the conventional polishing head structure shown in FIG. 3, illustrating a motion of the backing pad. In the conventional polishing head 1′, to make the load uniformly applied to the wafer, the water 8′ is enclosed as an incompressible fluid, thereby reducing the deformation of the backing pad at the small gap formed between the template 5 and the wafer W. However, it has been found that as shown in FIG. 4, the backing pad 3 is locally deformed at the outermost peripheral portion of the wafer W, and this deformation lowers the polishing uniformity at the outermost peripheral portion of the wafer W.

Specifically, when a polishing process is performed using the conventional polishing head, the stock removal variation is increased at the wafer outermost peripheral portion as shown in FIG. 6 (wafer position from 149 mm to 147 mm). Hence, uniform wafer polishing has been infeasible.

### CITATION LIST

### Patent Literature

Patent Document 1: WO 2010/023829

Patent Document 2: JP 2012-35393A

Patent Document 3: WO 2013/001719

### SUMMARY OF INVENTION

### Technical Problem

As described above, a wafer pasted, with water, on the template of the polishing head is polished while the pressure applied from the back plate via the fluid enclosed in the space pushes the backing pad of the template to transmit the load.

In the conventional wafer polishing head, to uniformly apply the load to the wafer, water is enclosed as an incompressible fluid in the space, thereby reducing the deformation of the backing pad at the small gap formed between the template and the wafer. It has been found, however, that water having a fluid viscosity of 0.890 mPa·s (25° C.) is not sufficient to improve the polishing uniformity around the outermost peripheral portion of a wafer. It is necessary to further reduce the deformation of the backing pad at the gap.

The present invention has been made in view of the above-described problems. An object of the present invention is to provide a polishing head and a polishing method which are capable of reducing the deformation of a backing pad at a small gap between a template and a wafer in comparison with a conventional polishing head, and improving the polishing uniformity at the outermost peripheral portion of the wafer.

### Solution to Problem

To achieve the object, the present invention provides a polishing head comprising at least:

an annular ceramic ring;

a template attached to the ceramic ring and having a backing pad and a guide ring integrated therewith; and

a back plate joined to the ceramic ring to form a space together with the backing pad and the ceramic ring,

the polishing head being configured to hold a back surface of a wafer on a lower surface portion of the backing pad and to bring a front surface of the wafer into sliding contact with a polishing pad attached on a turntable for polishing the wafer, wherein

an incompressible fluid is enclosed in the space, and

the incompressible fluid has a viscosity of 10 mPa·s or more and 1200 mPa·s or less.

With such a polishing head, the space is formed between the back plate and the ceramic ring with the template attached thereto, and the incompressible fluid enclosed in the space has a viscosity as high as 10 mPa·s or more and 1200 mPa·s or less. This makes it possible to reduce deformation of the backing pad in a small gap between the template and the wafer, while fluid-induced local deformation of the backing pad is reduced. This enables improvement in uniformity precision of stock removal of the wafer outer peripheral portion.

In this case, the incompressible fluid is preferably a water-soluble polymer dissolved in water.

Such a polishing head can change the viscosity of the incompressible fluid through the concentrations of water and the water-soluble polymer such as PVA (polyvinyl alcohol). Thus, appropriately adjusting the viscosity enables uniform polishing stock removal of the wafer outer peripheral portion more reliably. In this event, the fluid to be enclosed is not particularly limited, as long as the viscosity thereof is 10 mPa·s or more and 1200 mPa·s or less.

Moreover, the present invention provides a wafer polishing method using the polishing head, the method comprising:

supplying a polishing agent onto the polishing pad attached on the turntable; and

bringing the front surface of the wafer held by the polishing head into sliding contact with the polishing pad to polish the wafer.

Such a wafer polishing method makes it possible to reduce deformation of the backing pad in a small gap between the template and the wafer, while reducing local deformation of the backing pad. This enables improvement in uniformity precision of stock removal of the wafer outer peripheral portion.

### Advantageous Effects of Invention

According to the inventive polishing head and wafer polishing method, an incompressible fluid having a viscosity of 10 mPa·s or more and 1200 mPa·s or less is enclosed in the space formed between the back plate and the ceramic ring to which the template is attached. This makes it possible to reduce the local deformation of the backing pad in a small gap formed between the template and a wafer, and enables uniform stock removal in polishing the wafer.

### BRIEF DESCRIPTION OF DRAWINGS

FIG. 1 is a view showing an example of a polishing head structure of the present invention.

FIG. 2 is an enlarged view of an exemplary section surrounded by the dashed line in the inventive polishing head structure shown in FIG. 1.

FIG. 3 is a view showing an example of a conventional polishing head structure.

FIG. 4 is an enlarged view of an exemplary section surrounded by the dashed line in the conventional polishing head structure shown in FIG. 3, illustrating a motion of a backing pad.

FIG. 5 is an enlarged view of the exemplary section surrounded by the dashed line in the inventive polishing head structure shown in FIG. 1, illustrating a motion of a backing pad.

FIG. 6 is a graph showing a wafer shape profile when the wafer is polished using the conventional polishing head.

FIG. 7 is a graph showing a relation between the concentration and the viscosity of a water-soluble polymer.

FIG. 8 is a graph showing wafer shape profiles in Examples 1 to 3 and Comparative Example 1.

FIG. 9 is a graph showing thickness variations at wafer outer peripheral portions (within the wafer radius: 149 mm to 147 mm) in Examples 1 to 3 and Comparative Example 1.

FIG. 10 is a graph showing ΔSFQR(max) in Example 4 and Comparative Example 2.

FIG. 11 is a graph showing ΔESFQR(max) in Example 4 and Comparative Example 2.

FIG. 12 shows explanatory views for explaining a method of enclosing an incompressible fluid: (A) shows a case where the guide ring thickness is smaller than the wafer thickness; and (B) shows a case where the guide ring thickness is larger than the wafer thickness.

FIG. 13 is a view showing an example of a polishing apparatus that can be used in the inventive polishing method.

### DESCRIPTION OF EMBODIMENTS

As described above, in the conventional wafer polishing head, water is enclosed as an incompressible fluid in the space to uniformly apply the load to a wafer, thereby reducing the deformation of the backing pad at a small gap formed between the template and the wafer. However, it has been found that water, which has a fluid viscosity of 0.890 mPa·s (25° C.), is insufficient to improve the polishing uniformity at the wafer outermost peripheral portion. Hence, it is necessary to further reduce the deformation of the backing pad at the gap.

Accordingly, the present inventors have earnestly studied to solve the above-described problems and consequently found that when an incompressible fluid having a viscosity of 10 mPa·s or more and 1200 mPa·s or less is enclosed in the space, deformation of the backing pad at the gap can be reduced, and uniform stock removal is achieved around the wafer outer peripheral portion. Thus, the inventors have arrived at the present invention. Note that if the incompressible fluid has a viscosity of more than 1200 mPa·s, it is impossible to enclose the incompressible fluid.

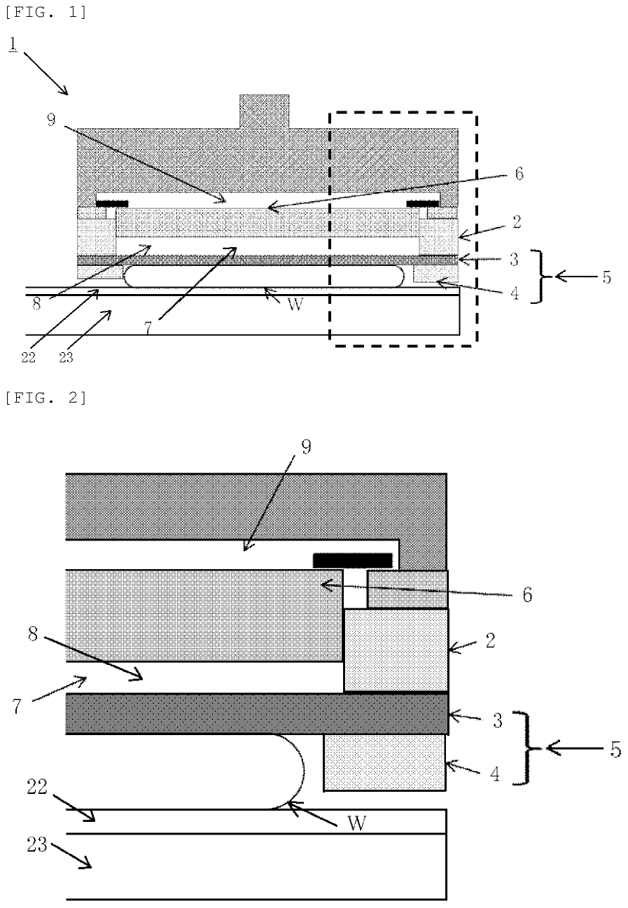

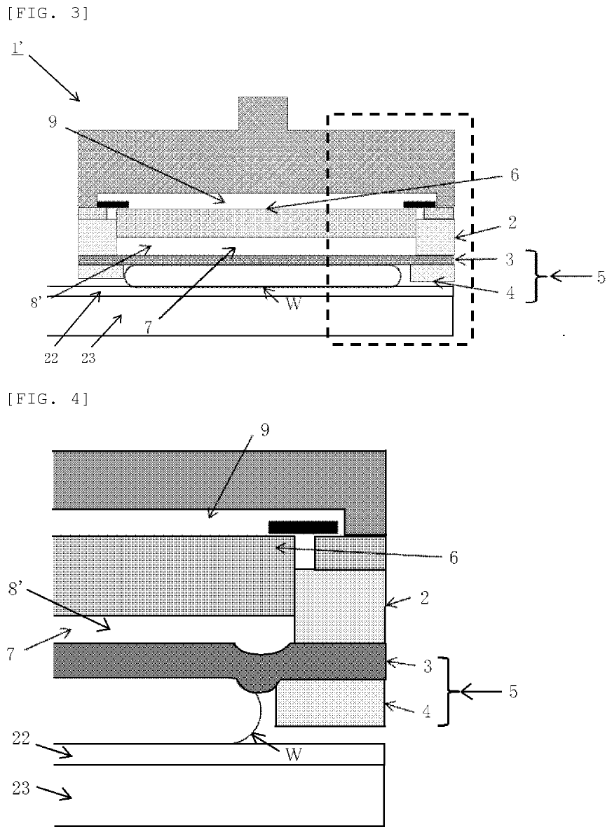

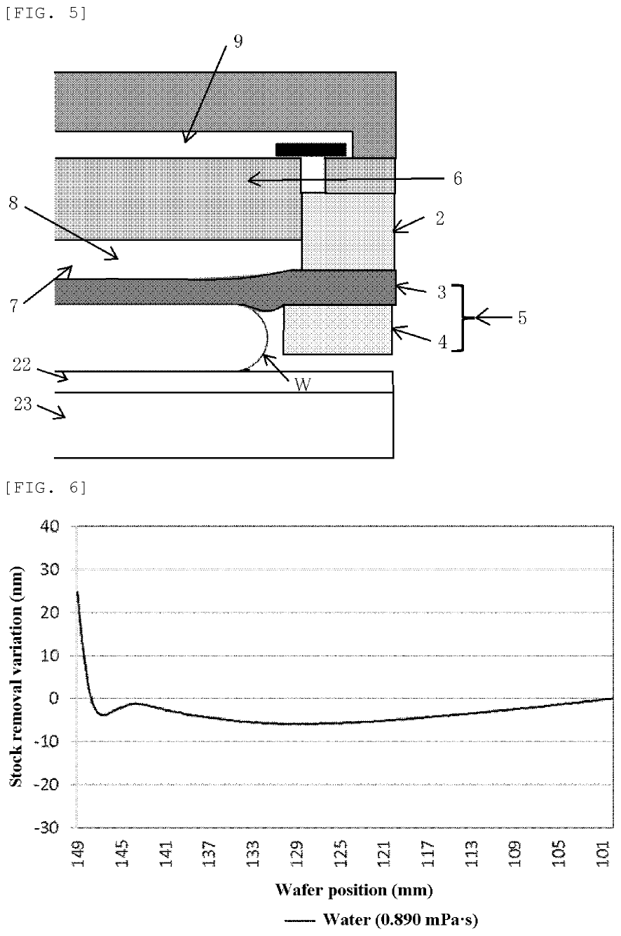

FIG. 1 is a view showing an example of a polishing head structure of the present invention. Moreover, FIG. 2 is an enlarged view of an exemplary section surrounded by the dashed line in the inventive polishing head structure shown in FIG. 1. In a polishing head 1, a template 5 is attached to an annular ceramic ring 2. The template 5 has a backing pad 3 and a guide ring 4 which is made of a resin such as a glass epoxy material and integrated with the backing pad 3. A space 7 is formed between a back plate 6 and the ceramic ring 2 to which the template 5 is attached. An incompressible fluid 8 is enclosed in the space 7.

The viscosity of the incompressible fluid 8 is adjusted by dissolving a water-soluble polymer such as PVA (polyvinyl alcohol) in water. Conceivably, the most preferable concentration of the water-soluble polymer is 12 w % (viscosity: 90 mPa·s). Nevertheless, the incompressible fluid 8 enclosed in the polishing head 1 is not limited to an aqueous solution of the water-soluble polymer PVA. Additionally, regarding the concentration also, the viscosity is not limited to 90 mPa·s, and any concentration suffices as long as the resulting viscosity is 10 mPa·s or more and 1200 mPa·s or less.

After the incompressible fluid 8 is enclosed, an upper portion of the polishing head having a pressing mechanism such as a wafer presser 9 is mounted on an upper surface of the back plate 6.

In the polishing head 1, a wafer W is pasted on the template 5 with water, and the pressure applied from the back plate 6 via the incompressible fluid 8 enclosed in the space 7 pushes the backing pad 3 of the template 5, and the load is transmitted to polish the wafer W.

In this event, the polishing head 1 holds a back surface of the wafer on a lower surface portion of the backing pad 3, and brings a front surface of the wafer into sliding contact with a polishing pad 22 attached on a turntable 23 to polish the front surface of the wafer.

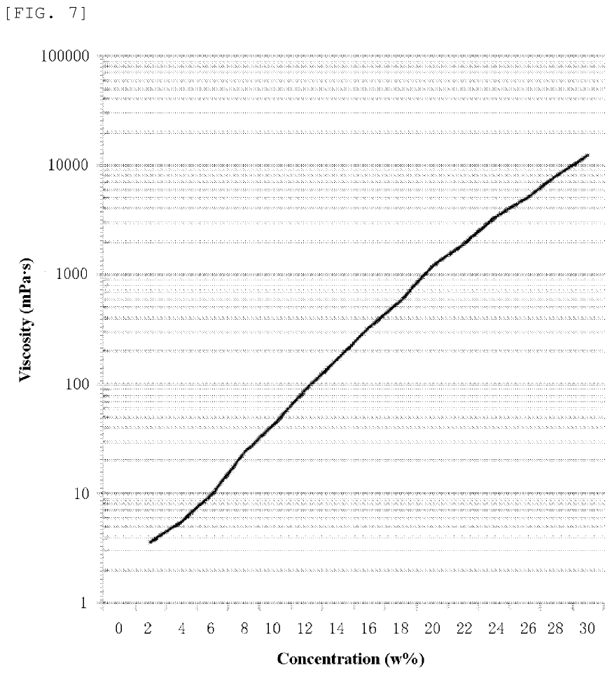

FIG. 5 is an enlarged view of the exemplary section surrounded by the dashed line in the inventive polishing head structure, illustrating a motion of the backing pad 3. In the inventive polishing head 1, local change of the backing pad 3 within a small gap formed between the template 5 and the wafer W is moderate, so that the pushing force on the wafer outer peripheral portion is reduced.

As described above, enclosing the incompressible fluid 8 having a viscosity of 10 mPa·s or more and 1200 mPa·s or less in the space 7 of the polishing head 1 reduces deformation of the backing pad 3 in the small gap formed between the template 5 and the wafer W, making it possible to improve the polishing uniformity at the wafer outermost peripheral portion.

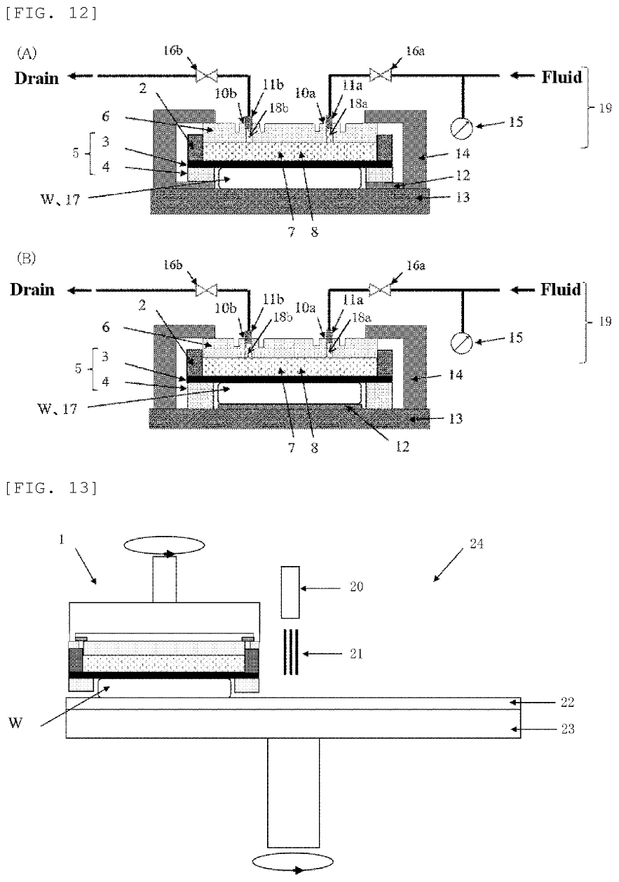

Now, a method of enclosing the incompressible fluid into the space 7 will be described. The incompressible fluid is enclosed using a fluid enclosing apparatus as shown in FIGS. 12(A) and (B).

FIG. 12(A) is a view showing an exemplary fluid-enclosing method in a case where the guide ring having a smaller thickness than the wafer is used. As shown in FIG. 12(A), in the polishing head, two through holes 18a, 18b through which the incompressible fluid 8 is introduced into and discharged from the space 7 are provided in the upper surface of the back plate 6. Couplers 10a, 10b are respectively mounted in the through holes 18a, 18b to enclose the incompressible fluid 8 in the space 7 while the pressure of the incompressible fluid 8 (hereinafter may be abbreviated as enclosing pressure) is kept. When the incompressible fluid 8 is enclosed in the space 7 before the wafer W is polished, a fluid enclosing apparatus 19 is first connected to the polishing head as follows, for example.

As shown in FIG. 12(A), the fluid enclosing apparatus 19 has a channel for introducing the incompressible fluid 8, and the channel is connected to a manometer 15 and a valve 16a. One end of the channel is connected to a nipple 11a. The nipple 11a is connected to the coupler 10a provided in the back plate 6. Further, the fluid enclosing apparatus 19 has a channel for discharging the incompressible fluid 8. This channel is connected to a drain at one end and connected to a valve 16b in the middle. The other end of the channel is connected to a nipple 11b. The nipple 11b is connected to the coupler 10b provided in the back plate 6.

Next, the wafer W or an adjustment plate 17 having the same thickness as the wafer W is placed on a flat base 13. An adjustment spacer 12 is placed on a lower surface of the guide ring 4, and has a thickness that is equal to a thickness difference between the wafer W and the guide ring 4. Further, the polishing head members including the backing pad 3, the guide ring 4, the ceramic ring 2, and the back plate 6 are placed on the base 13 such that the wafer W or the adjustment spacer 12 is housed in a hole of the guide ring 4. Furthermore, the base 13 and the back plate 6 are fixed with a clamp jig 14 to keep the height of the back plate 6 from changing when the incompressible fluid 8 is enclosed.

Next, the valves 16a and 16b are opened to introduce the incompressible fluid 8 into the space 7, and the space 7 is deflated. The deflation can be performed, for example, by closing the valve 16a, opening the valve 16b, and connecting a pressure-reducing channel to the drain side.

Next, the valve 16a and 16b are closed, and the pressure is adjusted with an unillustrated pressure adjusting mechanism for the incompressible fluid 8 such that the manometer 15 indicates a predetermined pressure. Then, the valve 16a is opened to introduce the incompressible fluid 8 into the space 7. After it is confirmed that the manometer 15 indicates a predetermined pressure, the valve 16a is closed, so that the incompressible fluid 8 is enclosed in the space 7. After the enclosure, the nipples 11a and 11b are detached from the couplers 10a and 10b mounted on the upper portion of the back plate 6.

FIG. 12(B) is a view showing an exemplary method of enclosing the incompressible fluid in a case where the guide ring having a larger thickness than the wafer is used. In this case, as shown in FIG. 12(B), the adjustment spacer 12 is inserted under the lower surface of the wafer W. The incompressible fluid 8 can be enclosed in the same manner as described above.

Alternatively, in a case where the thickness of the wafer W is equal to the thickness of the guide ring 4, the incompressible fluid 8 may be enclosed without using the adjustment spacer.

Next, the inventive polishing method will be described. FIG. 13 is a schematic view showing an example of a polishing apparatus that can be used in the inventive polishing method. As shown in FIG. 13, a polishing apparatus 24 has a polishing pad 22 attached on a turntable 23, a polishing-agent-supplying mechanism 20 for supplying a polishing agent 21 onto the polishing pad 22, and the above-described inventive the polishing head 1 as a polishing head for holding a wafer W. The polishing head 1 has a structure enabling a pressing mechanism such as a wafer presser 9 to press the wafer W against the polishing pad 22 attached to the turntable 23.

While the polishing-agent-supplying mechanism 20 supplies the polishing agent 21 onto the polishing pad 22, a front surface of the wafer W is brought into sliding contact therewith by rotation motion of the polishing head 1 linked to a rotation shaft and rotation motion of the turntable 23 to polish the wafer W.

According to such a polishing method, the incompressible fluid 8 which has a viscosity of 10 mPa·s or more and 1200 mPa·s or less is enclosed in the space 7. This makes it possible to uniformly apply the load to the wafer, enabling uniform stock removal of the wafer outer peripheral portion.

### EXAMPLE

Hereinafter, the present invention will be specifically described with reference to Examples and Comparative Examples. However, the present invention is not limited thereto.

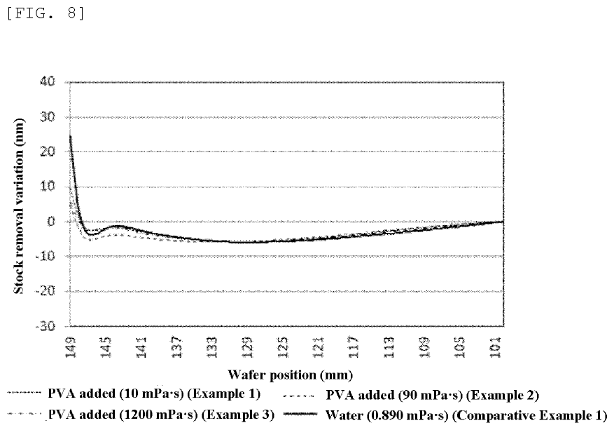

First, PVA (polyvinyl alcohol) was dissolved in water, which is one of incompressible fluids, and the viscosity of the resultant was measured in a 25° C. environment with a Brookfield viscometer. FIG. 7 is a graph showing a relation between the concentration and the viscosity of the water-soluble polymer. Changes in the viscosity relative to the PVA concentration (w %) were checked by changing the proportion of PVA to be dissolved. Thus, the concentration of the fluid to be supplied into the head was determined.

### Examples 1 to 3

The changes in the viscosity relative to the PVA concentration were checked, and the PVA concentration in the fluid to be enclosed into the polishing head was set at three levels: 6 w % (10 mPa·s) (Example 1), 12 w % (90 mPa·s) (Example 2), and 20 w % (1200 mPa·s) (Example 3).

Then, each of the incompressible fluids at the three levels was enclosed into the polishing head at the same pressure (approximately 15 kPa), and wafer polishing was performed. The differences in stock removal profiles before and after the process were compared.

As described above, each incompressible fluid was enclosed using the fluid enclosing apparatus shown in FIG. 12(A), (B). In this event, when the template thickness was 700 μm (when the guide ring having a smaller thickness than the wafer was used), the adjustment spacer 12 of 75 μm was inserted under the lower surface of the template 5. When the template thickness was 780 μm (when the guide ring having the same thickness as the wafer thickness was used), the adjustment spacer was not used. When the template thickness was 800 μm (when the guide ring having a larger thickness than the wafer was used), an adjustment spacer of 25 μm was inserted under the lower surface of the wafer. In this manner, each fluid was enclosed.

The polishing conditions were as follows.

### [Polishing Conditions]

Apparatus: a single-side polishing machine manufactured by Fujikoshi Machinery Corp.

Processed wafer: <100> silicon wafer with a diameter of 300 mm rated as P⁻ product

Polishing pad: secondary polishing cloth made of unwoven fabric

Polishing agent: secondary polishing slurry containing KOH-based colloidal silica

Moreover, the stock removal after the polishing was measured using a flatness measurement system WaferSight 2 manufactured by KLA-Tencor.

### Comparative Example 1

Wafer polishing was performed under the same conditions as those in Examples 1 to 3, except for using a conventional polishing head as shown in FIG. 3 in which the water 8′ was enclosed in the space 7.

FIG. 8 shows wafer shape profiles in Examples 1 to 3 and Comparative Example 1. As shown in FIG. 8, when the incompressible fluid enclosed in the space had a viscosity of 10 mPa·s or more and 1200 mPa·s or less, more uniform stock removal was achieved at the wafer outer peripheral portion. In other words, the stock removal variation at the wafer outer peripheral portion was smaller in Examples 1 to 3 than in Comparative Example 1.

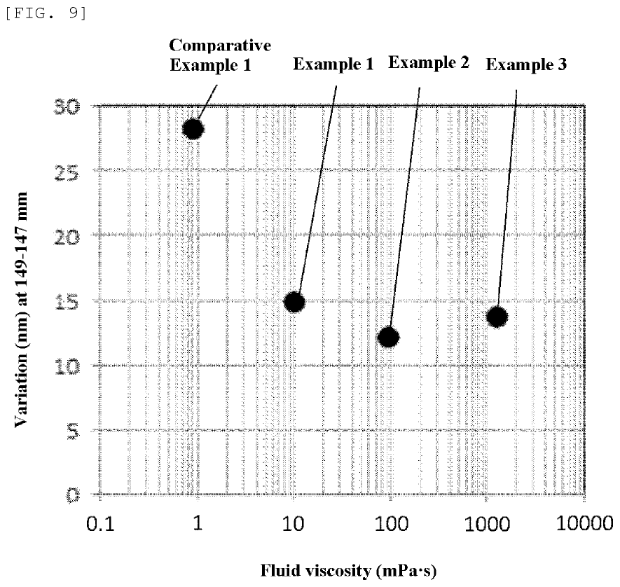

Next, changes in thickness at positions 149 mm to 147 mm in the wafer radius were compared among the fluid viscosities. FIG. 9 is a graph showing thickness variations at the wafer outer peripheral portions (wafer radius: 149 mm to 147 mm) in Examples 1 to 3 and Comparative Example 1. When the fluids having higher viscosity (10 mPa·s or more and 1200 mPa·s or less) than conventionally-adopted water (0.890 mPa·s) were used, the thickness variations at the wafer outer peripheral portions were reduced, and the stock removal uniformity was improved. Example 2 (viscosity: 90 mPa·s) resulted in the smallest variation. With the range of 10 mPa·s or more and 1200 mPa·s or less, significant improvements in stock removal uniformity were observed.

### Example 4, Comparative Example 2

The inventive polishing head enclosing a fluid with a viscosity of 90 mPa·s (Example 4) and a conventional polishing head enclosing water with a viscosity of 0.890 mPa·s (Comparative Example 2) were used to perform polishing of ten wafers per each type of polishing heads. The ΔESFQR(max) and ΔSFQR(max) before and after the polishing processes were compared.

The incompressible fluids were enclosed and the polishing processes were performed in the same manners as in Examples 1 to 3.

Moreover, after these polishing, the quality evaluations (ΔSFQR(max) and ΔESFQR(max) of the silicon wafers) were performed using a flatness measurement system WaferSight 2 manufactured by KLA-Tencor.

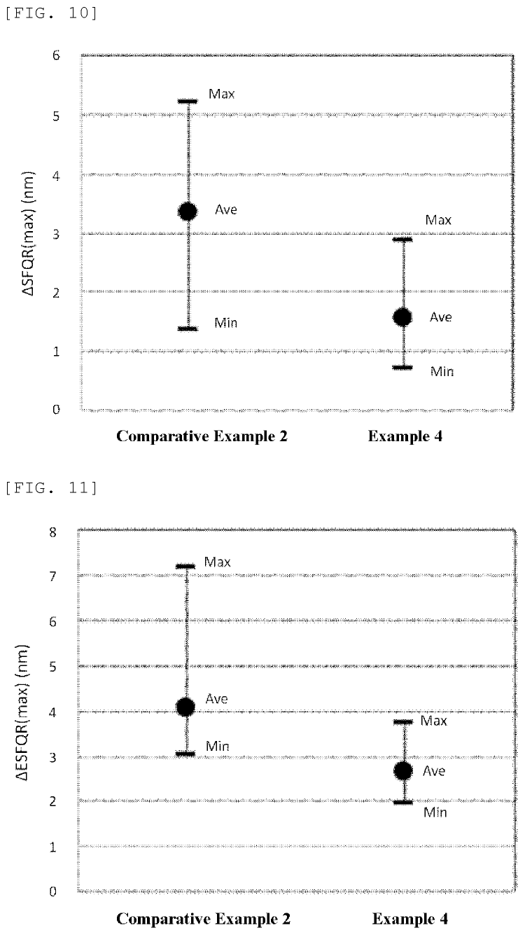

FIG. 10 and FIG. 11 show the comparison results of ΔSFQR(max) and ΔESFQR(max) as the changes before and after the wafer polishing processes in Comparative Example 2 and Example 4 in which the polishing processes were performed using the conventional polishing heads and the inventive polishing heads, respectively.

The results revealed that the inventive polishing head enclosing the fluid with a viscosity of 90 mPa·s (Example 4) exhibited smaller flatness variations as a result of significantly smaller ΔESFQR(max) and ΔSFQR(max) than the conventional polishing head (Comparative Example 2).

As has been described above, when an incompressible fluid enclosed in the polishing head has a viscosity of 10 mPa·s or more and 1200 mPa·s or less, it is possible to improve stock removal uniformity.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A polishing head comprising at least:
an annular ceramic ring;
a template attached to the ceramic ring and having a backing pad and a guide ring integrated therewith; and
a back plate joined to the ceramic ring to form a space together with the backing pad and the ceramic ring,
the polishing head being configured to hold a back surface of a wafer on a lower surface portion of the backing pad and to bring a front surface of the wafer into sliding contact with a polishing pad attached on a turntable for polishing the wafer, wherein
an incompressible fluid is enclosed in the space, and
the incompressible fluid has a viscosity of 10 mPa·s or more and 1200 mPa·s or less.

2. The polishing head according to claim 1, wherein the incompressible fluid is a water-soluble polymer dissolved in water.

3. A wafer polishing method using the polishing head according to claim 1, the method comprising:
supplying a polishing agent onto the polishing pad attached on the turntable; and
bringing the front surface of the wafer held by the polishing head into sliding contact with the polishing pad to polish the wafer.

4. A wafer polishing method using the polishing head according to claim 2, the method comprising:
supplying a polishing agent onto the polishing pad attached on the turntable; and
bringing the front surface of the wafer held by the polishing head into sliding contact with the polishing pad to polish the wafer.
